(19) United States
(12) Patent Application Publication
(10) Pub. No.: US 2024/0332281 A1
(43) Pub. Date: Oct. 3, 2024

(54) SEMICONDUCTOR DEVICE

(71) Applicant: National Institute of Advanced Industrial Science and Technology, Tokyo (JP)

(72) Inventors: Akira NAKAJIMA, Ibaraki (JP); Shinsuke HARADA, Ibaraki (JP); Kazutoshi KOJIMA, Ibaraki (JP)

(73) Assignee: National Institute of Advanced Industrial Science and Technology, Tokyo (JP)

(21) Appl. No.: 18/737,031

(22) Filed: Jun. 7, 2024

Related U.S. Application Data
(63) Continuation of application No. PCT/JP2022/043169, filed on Nov. 22, 2022.

(30) Foreign Application Priority Data
Dec. 9, 2021 (JP) 2021-199975

(51) Int. Cl. H01L 27/02; H01L 29/20; H01L 29/778

(52) U.S. Cl. CPC H01L 27/0255; H01L 29/2003; H01L 29/7786

(57) ABSTRACT

A destructive breakdown mode that leads to the destruction of a device is suppressed, in the case where a gallium nitride-based high electron mobility transistor is used as a power device. A diode is connected in antiparallel to a HEMT, and this antiparallel connected diode is designed such that an avalanche breakdown occurs therein before the drain-source voltage, which is the difference between the drain potential applied to a drain electrode and the source potential applied to a source electrode, exceeds the withstand voltage of the HEMT.

### CROSS-REFERENCE TO RELATED APPLICATIONS

The present application is a Bypass Continuation of International Application No. PCT/JP2022/043169 filed on Nov. 22, 2022, which claims priority from Japanese Application No. 2021-199975 filed on Dec. 9, 2021. The contents of these applications are hereby incorporated by reference into this application.

### TECHNICAL FIELD

The present invention relates to a semiconductor device, and relates for example, to an effective technique applied to a semiconductor device including a high electron mobility transistor and a diode.

### BACKGROUND ART

JP 2007-226475 A (Patent Literature 1) describes a semiconductor device integrated with a GaN-based field effect transistor, and a diode as a protection device thereof. Gallium nitride (GaN), silicon carbide (SiC) and silicon (Si) in particular are exemplified as substrates forming a diode, where a Schottky diode is configured to be formed over the back surface opposite to the element formation surface of the substrate.

JP 2009-004398 A (Patent Literature 2) describes a semiconductor device integrated with a GaN-based lateral high electron mobility transistor and a diode. Further described therein as diodes are a silicon-based lateral PN junction diode, a silicon-based vertical Schottky barrier diode, and a silicon carbide-based vertical Schottky diode.

JP 2010-010262 A (Patent Literature 3) describes a semiconductor device integrated with a GaN-based lateral high electron mobility transistor and a PN junction diode formed over a silicon substrate. Further described therein is that the PN junction diode is a lateral PN junction diode formed by ion implantation on a silicon substrate.

JP 2010-267958 A (Patent Literature 4) describes a semiconductor device integrated with a GaN-based lateral high electron mobility transistor and a PN junction diode. Further described therein is that the PN junction diode is a GaN-based lateral PN junction diode and a silicon-based vertical PN junction diode.

JP 2019-004084 A (Patent Literature 5) describes a semiconductor device integrated with an element on a silicon carbide substrate on which a GaN-based lateral high electron mobility transistor and a silicon carbide-based vertical junction type field effect transistor were connected in series. Since the drain electrode of the silicon carbide-based junction type field effect transistor is formed at the back surface opposite to the element formation surface of the silicon carbide substrate, the current path serves as a thickness direction of the silicon carbide substrate.

Non patent literature 1 describes a technique of performing epitaxial growth of an AlGaN/GaN HEMT structure on a silicon carbide substrate having an OFF angle of 0 degrees to 2 degrees.

### CITATION LIST

### Patent Literature

Patent Literature 1: JP 2007-226475 A
Patent Literature 2: JP 2009-004398 A
Patent Literature 3: JP 2010-010262 A
Patent Literature 4: JP 2010-267958 A
Patent Literature 5: JP 2019-004084 A

### Non Patent Literature

Non patent literature 1: M. Leszczynski et al., ECS Transactions, 50 (3), (2012), pp. 163 to 171
Non patent literature 2: E. A. Jones et al., IEEE JOURNAL OF EMERGING AND SELECTED TOPICS IN POWER ELECTRONICS, VOL. 4, NO. 3, September 2016, pp. 707 to 719
Non patent literature 3: W. Saito et al., IEEE TRANSACTIONS ON ELECTRON DEVICES, VOL. 52, NO. 1, January 2005, pp. 106 to 111
Non patent literature 4: W. Saito et al., IEEE TRANSACTIONS ON ELECTRON DEVICES, VOL. 54, NO. 8, August 2007, pp. 1825 to 1830
Non patent literature 5: S. Karmalkar et al., Solid State Electronics 45, (2001), pp. 1645 to 1652
Non patent literature 6: T. Deguchi et al., ELECTRONICS LETTERS Vol. 48 No. 2, (2012), pp. 109 to 110
Non patent literature 7: O. Ambacher et al., Journal of Applied Physics, 85 (6), (1999), pp. 3222 to 3233

### SUMMARY OF INVENTION

### Technical Problem

Recently, the further highly efficient utilization of energy has become a crucial and urgent problem for a low-carbon society. Because a power loss reduction effect in power convertors such as inverters etc. can contribute to a highly efficient utilization of energy, the development of a power device configured of a power convertor is crucial. Amidst this research and development situation, as a power device material, the switching over to a nitride semiconductor such as SiC (silicon carbide) and GaN (gallium nitride)) etc. instead of Si (silicon) is being considered. This is because SiC and nitride semiconductors have a large critical electric field strength and forbidden band width (bandgap) compared to Si, and hence a high performance power device able to balance the reduction of the ON resistance and the insulating withstand voltage can be provided. Furthermore, the nitride semiconductor can produce a high electron mobility transistor by means of a hetero junction such as AlGaN/GaN, where the nitride semiconductor has a characteristic of superior high frequency compared to a SiC power MOSFET, which is advantageous in applications for small size and high frequency of power convertors.

However, in a high electron mobility transistor utilizing nitride semiconductor as a power device material, if a drain-source voltage exceeding a withstand voltage is applied, a recoverable breakdown; that is, an avalanche breakdown will not occur, but a destructive breakdown mode which leads to destruction with no recovery will occur. As a result, when utilizing a gallium nitride-based high electron mobility transistor as a power device, it is desirable to suppress the destructive breakdown mode which leads to destruction of the device.

### Solution to Problem

The semiconductor device in an embodiment comprises a PN junction diode formed over (e.g., disposed over, formed directly on) a silicon carbide substrate, and a high electron mobility transistor formed over (e.g., disposed over, formed directly on) the PN junction diode.

Here, the PN junction diode includes a silicon carbide epitaxial layer of a first conduction type formed over (e.g., disposed over, formed directly on) a silicon carbide substrate, and an electric field relaxation region of a second conduction type formed in the silicon carbide epitaxial layer, wherein the second conduction type is a conduction type that is reverse to the first conduction type.

In contrast, a high electron mobility transistor includes: a channel layer including a first nitride semiconductor layer; a barrier layer including a second nitride semiconductor layer in contact with the channel layer; a buffer layer including a third nitride semiconductor layer with a bandgap larger than that of the silicon carbide epitaxial layer, the buffer layer provided between the channel layer and the silicon carbide epitaxial layer; a source electrode in contact with a first region of the barrier layer; a drain electrode in contact with a second region of the barrier layer; and a gate electrode provided between the source electrode and drain electrode.

At this time, the silicon carbide epitaxial layer is electrically connected to the source electrode, and the electric field relaxation region is electrically connected to the drain electrode. Further, in a plan view, the electric field relaxation region includes a region extended from the drain electrode.

### Advantageous Effects of Invention

According to an embodiment, the destruction of a high electron mobility transistor can be prevented.

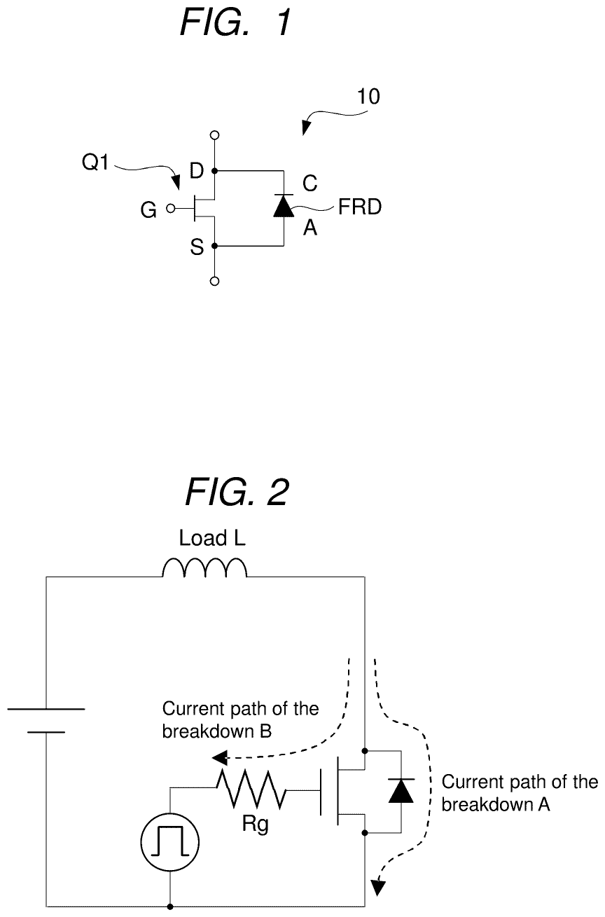

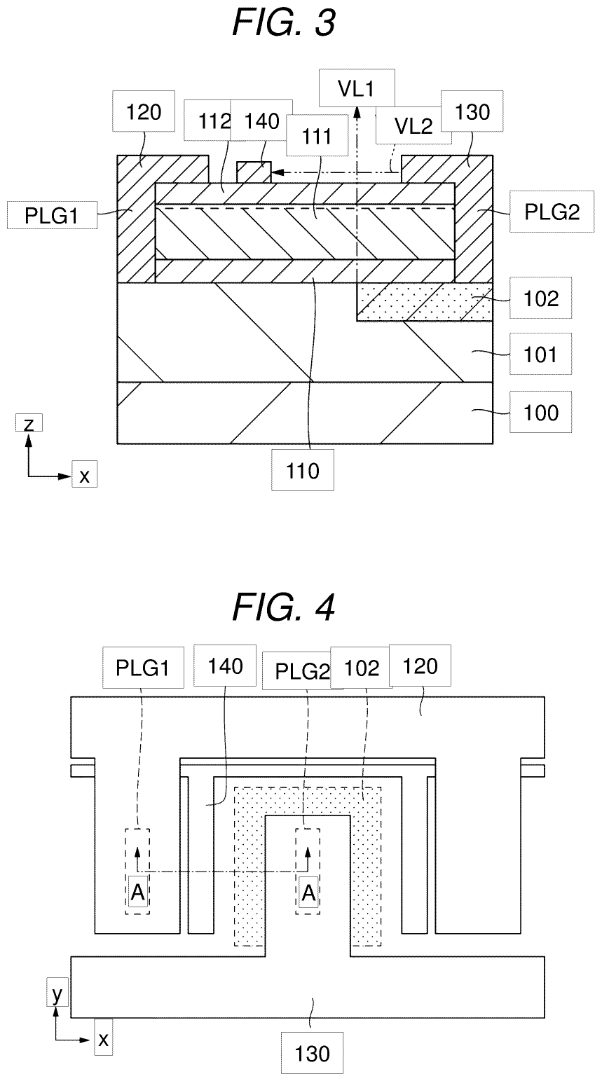

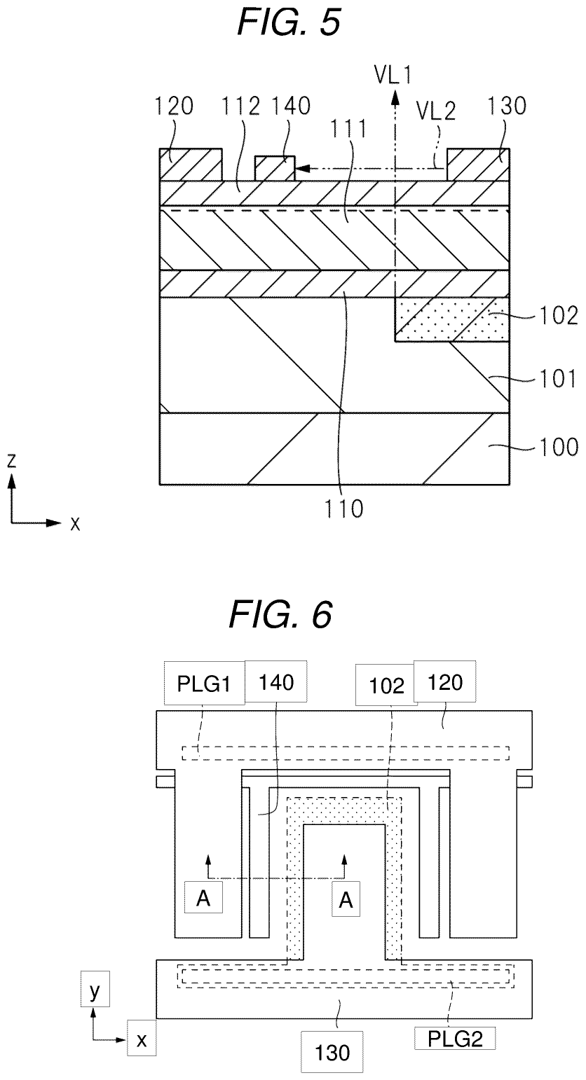

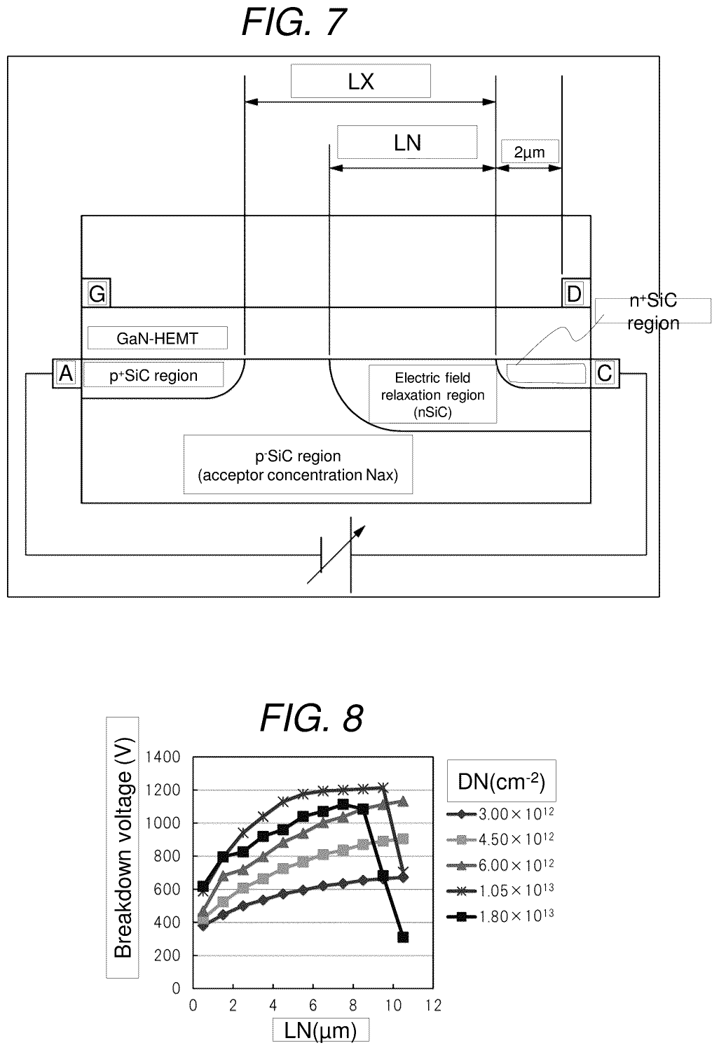

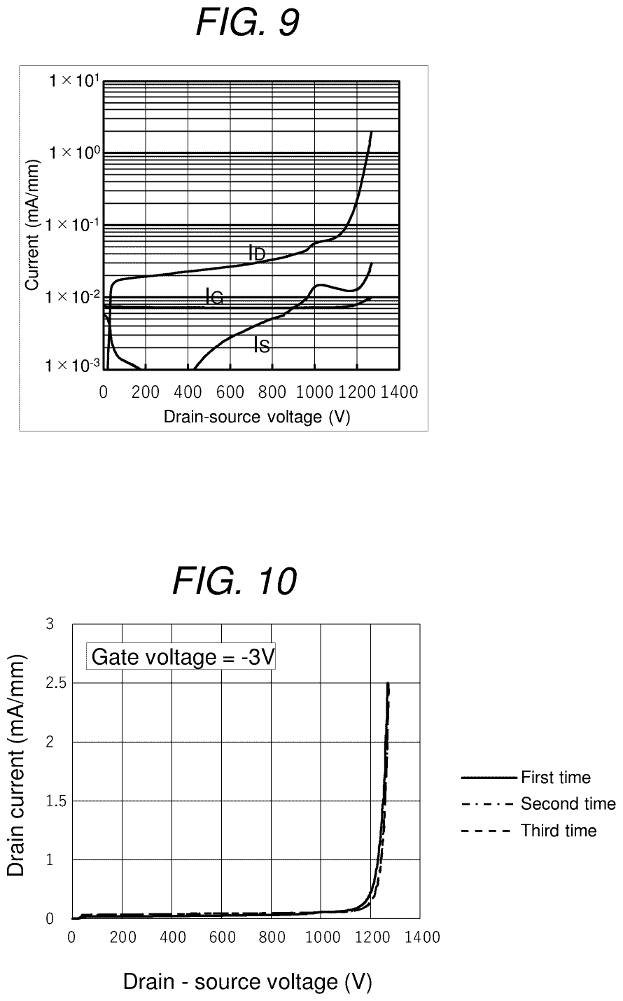

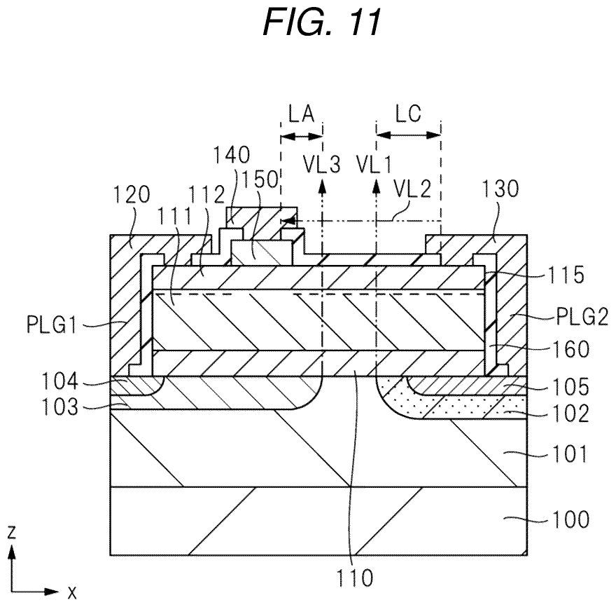

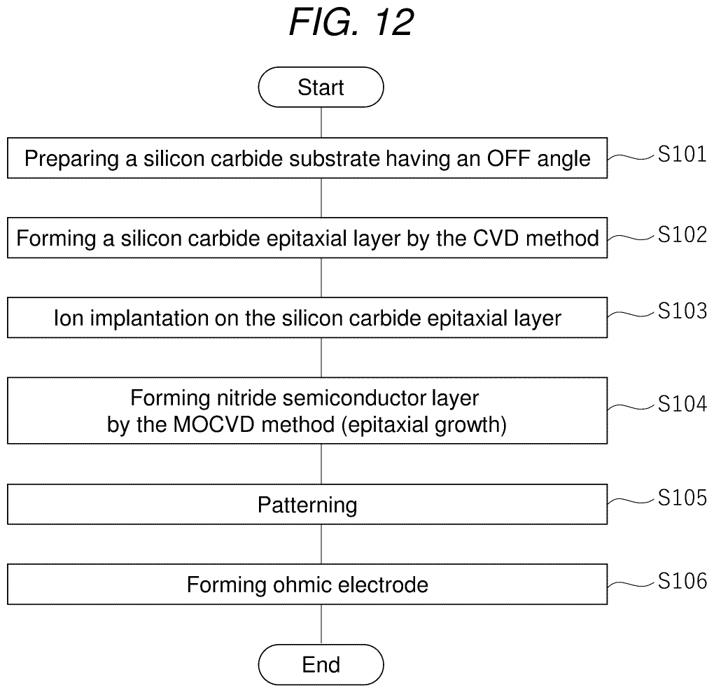

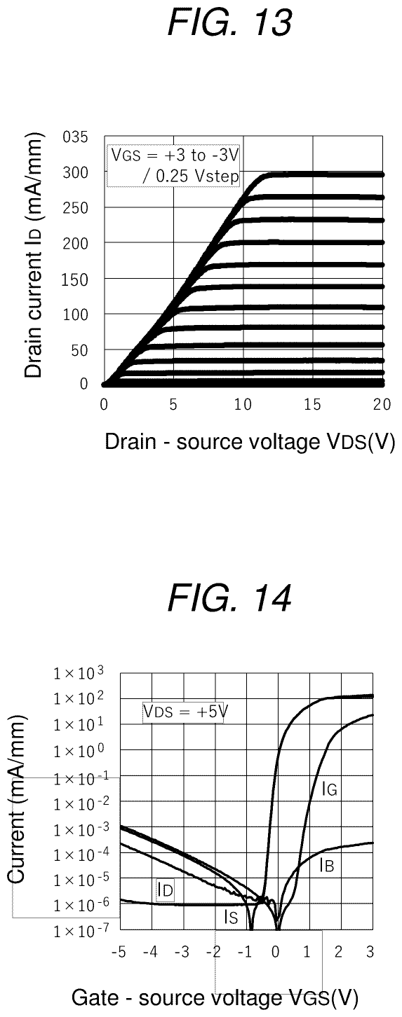

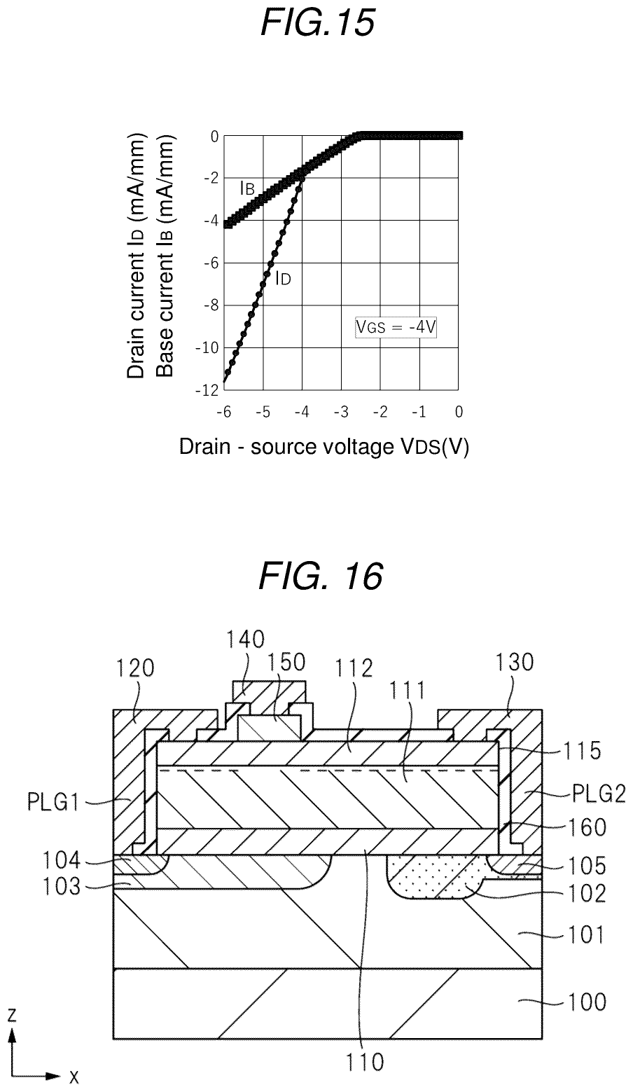

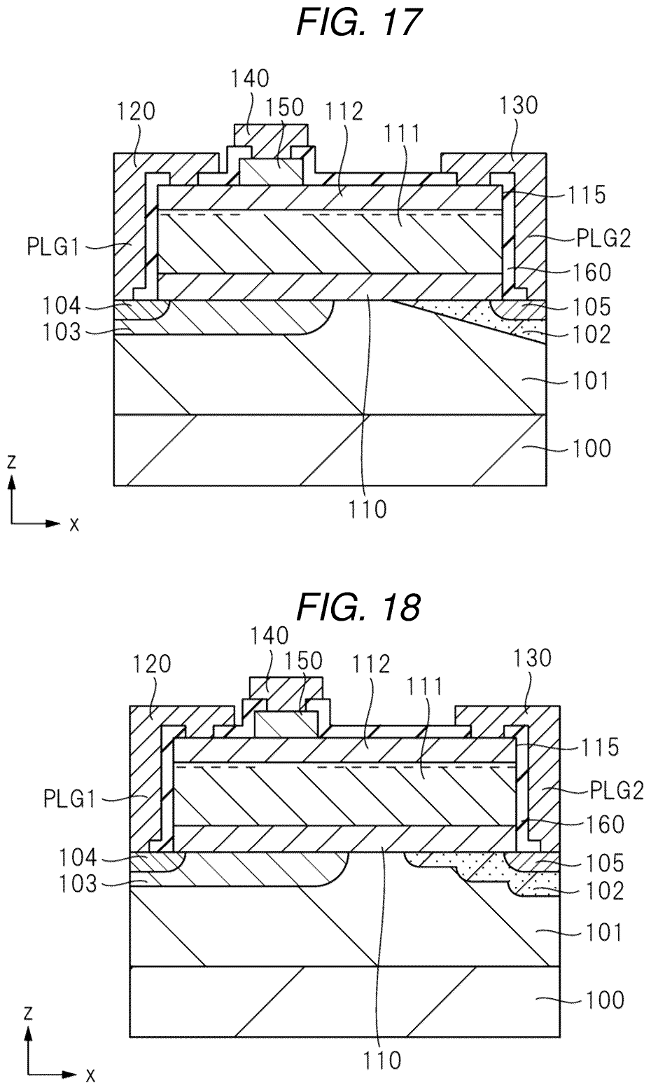

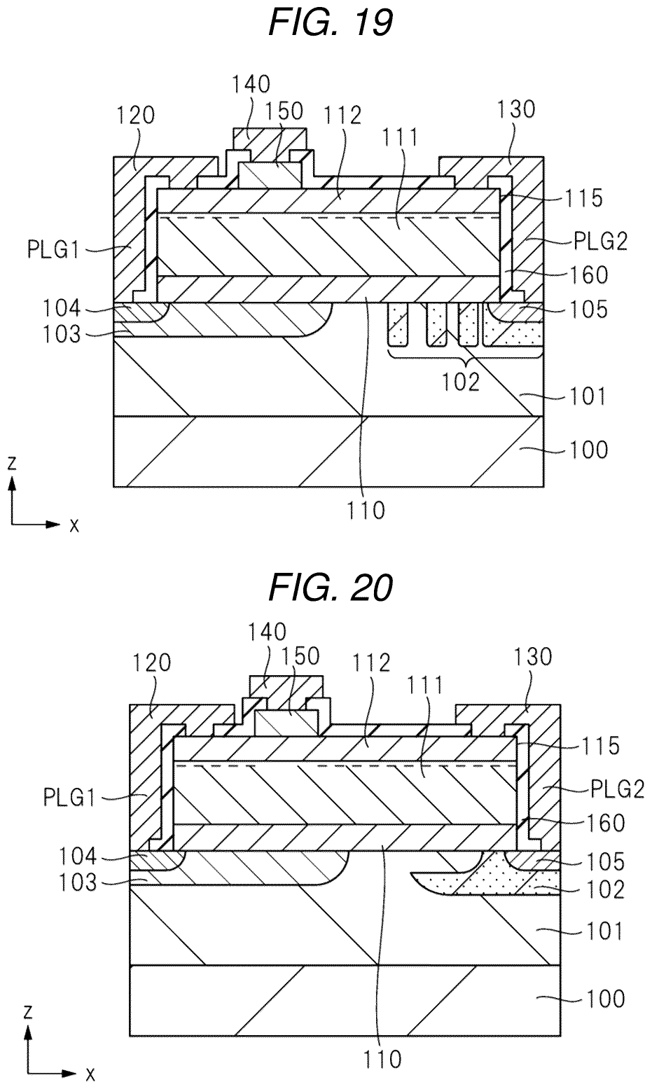

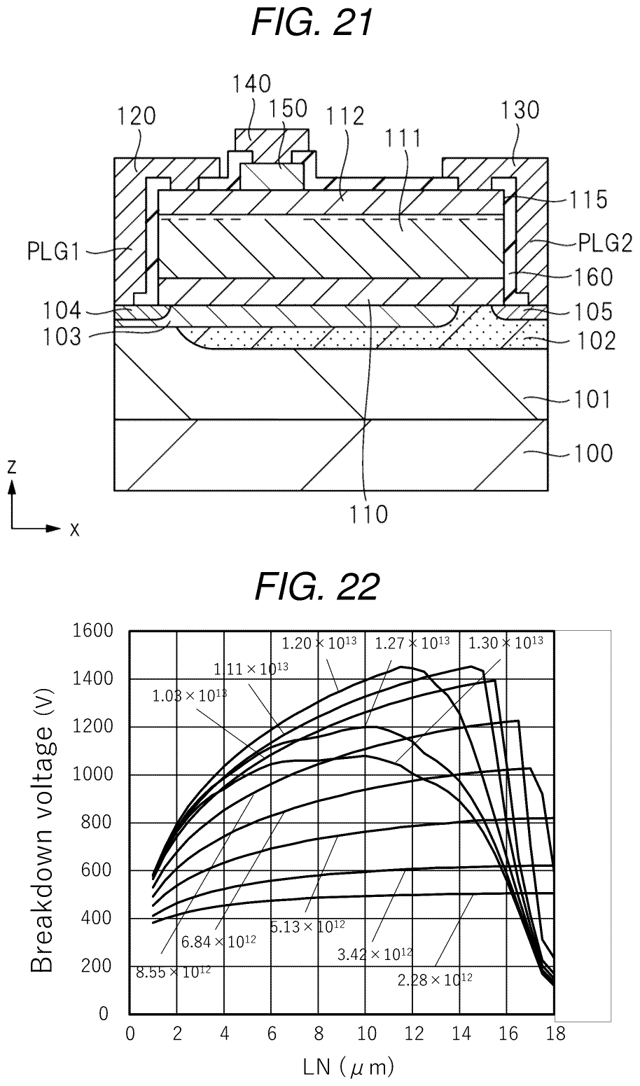

### BRIEF DESCRIPTION OF DRAWINGS

[FIG. 1] is a drawing illustrating configuration example of a switching circuit.

[FIG. 2] is a drawing illustrating a UIS test circuit.

[FIG. 3] is a sectional view illustrating a configuration of a semiconductor device based on the fundamental ideas.

[FIG. 4] is a plan view illustrating of a configuration of a semiconductor device based on the fundamental ideas.

[FIG. 5] is a sectional view illustrating a modified example of semiconductor device based on the fundamental ideas.

[FIG. 6] is a plan view illustrating a modified example of semiconductor device based on the fundamental ideas.

[FIG. 7] is a drawing illustrating a device structure of which a simulation took place.

[FIG. 8] is a graph illustrating a simulation result.

[FIG. 9] is a graph illustrating an evaluation result of the withstand voltage test in the OFF state.

[FIG. 10] is a graph illustrating the result of multiple sweeps in the withstand voltage test.

[FIG. 11] is a sectional view illustrating a configuration of a semiconductor device of an embodiment.

[FIG. 12] is a flowchart illustrating the flow of manufacturing steps of a semiconductor device.

[FIG. 13] is a graph illustrating an experimentation result of Id-Vds characteristics in the ON state.

[FIG. 14] is a graph illustrating an experimentation result transmission characteristics at Vds=5V.

[FIG. 15] is a graph illustrating an experimentation result of Id-Vds characteristics for a negative Vds, at Vgs=−4V.

[FIG. 16] is a sectional view illustrating a modified example.

[FIG. 17] is a sectional view illustrating a modified example.

[FIG. 18] is a sectional view illustrating a modified example.

[FIG. 19] is a sectional view illustrating a modified example.

[FIG. 20] is a sectional view illustrating a modified example.

[FIG. 21] is a sectional view illustrating a modified example.

[FIG. 22] is a graph illustrating a simulation result.

### DETAILED DESCRIPTION OF EMBODIMENTS

In all the drawings for explaining the embodiments, the same reference numerals are appended to the same members in principle, hence repetitive explanations thereof are omitted. Moreover, hatching may also be drawn on plan views for ease of understanding the drawings.

### Configuration Example of a Switching Circuit

FIG. 1 is a drawing illustrating a configuration example of a switching circuit.

In FIG. 1, a switching circuit 10 has a power transistor Q1 and a diode FRD, where the power transistor Q1 and the diode FRD are connected in antiparallel. Namely, the power transistor Q1 has a gate electrode G, a source S and a drain D, while the diode FRD has an anode A and a cathode C. Further, the source S of the power transistor Q1 and the anode A of the diode FRD are electrically connected, while the drain D of the power transistor Q1 and the cathode C of the diode FRD are electrically connected. A gate control circuit (not shown) is connected to the gate electrode G of the thus configured power transistor Q1, so that the switching action (ON/OFF action) of the power transistor Q1 is controlled by means of this gate control circuit.

### Types of Switching Elements

Examples of the power transistor Q1 can include a power MOSFET, an IGBT (Insulated Gate Bipolar Transistor), a junction type field effect transistor (JFET), a high electron mobility transistor (HEMT) etc.

### Diodes

When, for example, the IGBT is utilized as the power transistor Q1, the diode FRD which is connected in antiparallel to the IGBT must be provided.

From the viewpoint of achieving a switching function by means of the power transistor Q1, it is simply considered that while the IGBT is necessary as the power transistor Q1, it is not necessary to provide the diode FRD. In relation to this point, when an inductance is included in a load connected to the switching circuit 10, such as, e.g., when the load is a motor, the diode FRD must be provided. The reason for this will be explained below.

When a load is a pure resistance containing no inductance, the diode FRD is not necessary because there is no freewheeling energy. However, when a circuit containing an inductance such as a motor is connected to a load, there is a mode in which a load current flows in the direction reverse to that of a switch which is ON (freewheeling mode). Namely, if no inductance is contained in the load, the energy of the load returns from the inductance to the switching circuit 10 (the current flows in reverse).

At this time, the IGBT alone has no function for this freewheeling current to be able to flow, and hence it is necessary to connect the diode FRD in antiparallel to the IGBT. Namely, when including an inductance in a load such as a motor control in the switching circuit 10, the energy (1/2 LI²) stored in the inductance when the IGBT was turned OFF must be released without fail. However, with the IGBT alone, the freewheeling current for releasing the energy stored in the inductance cannot flow. Thus, in order to have the electric energy stored in this inductance freewheel, the diode FRD is connected in antiparallel to the IGBT. In other words, the diode FRD has a function of allowing the freewheeling current to flow, in order to release the electric energy stored in the inductance. Based on the above, when adopting the IGBT as the power transistor Q1 in the switching circuit 10 connected to a load containing an inductance, it is understood that the diode FRD must be provided in antiparallel to the IGBT. This diode FRD is called a “freewheeling diode”.

In contrast, when the power MOSFET is utilized as the power transistor Q1, for example, theoretically it is not necessary to provide the freewheeling diode connected in antiparallel to the power MOSFET. This is because with the power MOSFET device structure, a body diode which is a PN junction diode is inevitably parasitically formed and as result, this body diode functions as the freewheeling diode.

Furthermore, unlike the IGBT, the freewheeling diode does necessarily need to be provided in a unipolar transistor (junction type field effect transistor, high electron mobility transistor etc.), regardless of whether or not there is a body diode. This is because with a unipolar transistor, a source and drain have a symmetrical structure, hence a freewheeling mode current can flow. Accordingly, it can be said that by focusing on a high electron mobility transistor, it not necessarily required to provide the “freewheeling diode” based on the original objective; that is, allowing the freewheeling current to flow.

### Knowledge on the High Electron Mobility Transistor

As the power transistor Q1, we focus on the high electron mobility transistor (hereinunder, may be referred to as HEMT) utilizing gallium nitride, as follows.

In this case, as mentioned above, based on the original objective; that is, allowing the freewheeling current to flow, it can be said that it is not necessarily required to provide the “freewheeling diode”.

Here, with a HEMT utilizing a gallium nitride-based crystal as a power device material, when a drain-source voltage exceeding a withstand voltage is applied, a phenomenon peculiar to the HEMT is generated; that is, a destructive breakdown mode leading to destruction with no recovery is generated, not a recoverable breakdown such as an avalanche breakdown. As a result, when utilizing a gallium nitride-based HEMT as a power device, it is crucial to suppress the destructive breakdown mode leading to the destruction of the device.

A gallium nitride-based crystal is also called a Group III nitride semiconductor or a nitride semiconductor, and is a semiconductor as represented by GaN, AlN, InN and mixed crystals thereof (AlGaN, InGaN etc.). Names with omissions such as “gallium nitride-base” and “GaN-base” are also utilized.

Thus, from the viewpoint of suppressing the destructive breakdown mode leading to the destruction of a device, the present inventors investigated utilizing the aforementioned “freewheeling diode” in a gallium nitride-based HEMT. Namely, based on the original objective; that is, allowing the freewheeling current to flow, the present inventors focused on the “freewheeling diode” which is not necessarily required with a gallium nitride-based HEMT, and conceived of using this “freewheeling diode” from the viewpoint of suppressing the destructive breakdown mode leading to the destruction of the HEMT.

### Knowledge on the PN Junction Diode

We focus on a PN junction diode utilizing silicon carbide as the diode FRD, as follows. It is understood that, compared to a silicon PN junction diode, recovery loss can be greatly reduced with a PN junction diode utilizing silicon carbide.

However, as a diode utilizing silicon carbide, a unipolar type diode called a Schottky barrier diode is mainstream. There are very few examples where a bipolar type PN junction diode was put into practical application. This is because if the current of the PN junction diode utilizing silicon carbide is made to pass in the forward direction, an element degradation called a forward current degradation will occur. Here, the forward current degradation is a phenomenon attributable to a basal plane dislocation in relation to a SiC substrate, which occurs due to the enlarging of an originally existing crystal defect.

Thus, from the viewpoint of suppressing forward current degradation in a silicon carbide PN junction diode, the present inventors investigated a lateral PN junction diode whose current flows in the lateral direction (direction horizontal to the substrate surface). Namely, the present inventors conceived of utilizing a lateral PN junction diode which is not normally used, and not a vertical (direction perpendicular to the substrate surface) PN junction diode which is normally used with silicon carbide.

### Knowledge on Application to the Power Convertor of a Power Transistor

We further proceed with our investigation as follows on the premise that a non-destructive breakdown would be obtained by integrating a gallium nitride-based high electron mobility transistor with a PN junction diode. Specifically, we focus on the situation where the power transistor undergoes breakdown, and investigate the device operation thus required in the application to a power convertor.

As a test of envisaging a breakdown situation, a switching test by means of a UIS (Unclamped Inductive Switching) circuit is commonly performed in a power device. FIG. 2 is a circuit drawing illustrating a UIS test circuit. In FIG. 2, when a power transistor is turned ON, energy is accumulated from a direct current power source to a load L. When the power transistor is turned OFF after a predetermined amount of energy is accumulated, the drain voltage jumps up and it causes breakdown. At this time, it is crucial that a non-destructive avalanche breakdown occurs stably, and that the power transistor can absorb the accumulated energy of the load L. Specifically, it is required to allow a breakdown current to flow in the current path of the breakdown A of FIG. 2.

Meanwhile, if a current flows in the current path of the breakdown B, a mis-operation of the circuit occurs, a stable avalanche breakdown is destroyed, and the power transistor rushes into an oscillating mode where the ON and the OFF are repeated. Specifically, if a current flows in the current path of the breakdown B, the gate voltage rises by a finite gate resistance Rg, and becomes an oscillating mode repeatedly turning ON and OFF in error. In particular, even if a power transistor is a normally OFF type, in order for the turn OFF to become high-speed, a negative voltage relative to a source electrode during OFF is applied at a gate electrode. The gate electrode falls to the lowest potential, and there is a concern of inflow of holes generated by the avalanche breakdown. Accordingly, it becomes crucial to suppress a breakdown current of a power transistor flowing into the gate electrode.

Thus, the present inventors conceived of a structure in which a buffer layer with a large bandgap is provided between the gallium nitride-based HEMT and the aforementioned “freewheeling diode”, and thereby no breakdown current generated by the “freewheeling diode” flows into the HEMT.

### Fundamental Ideas of the Embodiments

The technical ideas based on this knowledge of the present inventors will be explained as follows.

A fundamental idea of the present embodiment is to connect a diode in antiparallel to the HEMT, where this antiparallel connected diode is designed so that an avalanche breakdown occurs therein before a drain-source voltage, which is the difference between a drain potential applied to a drain electrode and a source potential applied to a source electrode, exceeds a withstand voltage in the OFF state of the HEMT. Moreover, a fundamental idea also includes suppressing to the utmost the flow of electrons and holes (particularly holes) generated by the avalanche breakdown of the diode, into the gate electrode of the HEMT.

According to these fundamental ideas, the avalanche breakdown occurs in the diode before the drain-source voltage exceeds the withstand voltage of the HEMT, and thereby the destructive breakdown mode of the HEMT, which occurs when the drain-source voltage exceeds the withstand voltage of the HEMT, can be prevented. In other words, a fundamental idea of the present embodiment is that a diode is designed so that the avalanche breakdown occurs therein before the diode exceeds a withstand voltage of the HEMT, and thereby the destruction of the HEMT is prevented by clamping the drain-source voltage. Furthermore, a fundamental idea also includes inserting a semiconductor layer between the diode and the HEMT, where this layer has a bandgap energy larger than the bandgap energy of the semiconductor forming the diode, in order to prevent electrons and holes (particularly holes) generated due to the avalanche breakdown from flowing into the gate electrode.

Such fundamental ideas are innovative and superior technical ideas in that with the HEMT, from the viewpoint of suppressing the destructive breakdown mode that leads to the destruction of the HEMT, by focusing on a diode which is not necessarily required based on the original objective; that is, allowing the freewheeling current to flow, this diode is actively utilized to effectively suppress the occurrence of the destructive breakdown mode which is peculiar to the HEMT, and an erroneous turn ON is suppressed in the actual application to a power convertor.

### Semiconductor Device Based on the Fundamental Ideas

Next, a semiconductor device based on the aforementioned fundamental ideas will be explained.

FIG. 3 is a sectional view illustrating a configuration of a semiconductor device based on the fundamental ideas.

As illustrated in FIG. 3, a semiconductor device based on the fundamental ideas has a PN junction diode formed over (e.g., disposed over, formed directly on) a silicon carbide substrate 100, and a HEMT formed over (e.g., disposed over, formed directly on) the PN junction diode.

Specifically, the PN junction diode includes a p type silicon carbide epitaxial layer 101 formed over (e.g., disposed over, formed directly on) the silicon carbide substrate 100, and an electric field relaxation region (RESURF (REduced SURface Field) region) 102 which is formed in the silicon carbide epitaxial layer 101 and is an n type region. Namely, a PN junction is formed at the boundary region of the p type silicon carbide epitaxial layer 101 and the n type electric field relaxation region 102; as a result, a PN junction diode is configured by means of the p type silicon carbide epitaxial layer 101 and the n type electric field relaxation region 102. Here, the impurity concentration of an n type impurity (donor) introduced in the electric field relaxation region 102 is higher than the impurity concentration of a p type impurity (acceptor) introduced in the silicon carbide epitaxial layer 101.

Meanwhile, the HEMT includes a buffer layer 110 with a bandgap larger than that of the silicon carbide epitaxial layer 101, a channel layer 111 in contact with the buffer layer 110, a barrier layer 112 in contact with the channel layer 111, a source electrode 120 in contact with a first region of the barrier layer 112, a drain electrode 130 in contact with a second region of the barrier layer 112, and a gate electrode 140 provided between the source electrode 120 and drain electrode 130. With a HEMT configured in this way, two-dimensional electron gas is generated at the interface of the channel layer 111 and barrier layer 112. The silicon carbide epitaxial layer 101 is electrically connected to the source electrode 120 via a plug PLG1, and the electric field relaxation region 102 is electrically connected to the drain electrode 130 via a plug PLG2.

Further, in FIG. 3, when the stacking direction of the PN junction diode and high electron mobility transistor is configured as the first direction (z direction of FIG. 3), and the direction from the drain electrode 130 facing towards the gate electrode 140 is configured as the second direction (−x direction of FIG. 3), in a cross-sectional view, a first virtual line VL1 made to extend (e.g., extending) from an edge of the electric field relaxation region 102 in the z direction intersects with a second virtual line VL2 made to extend (e.g., extending) in the −x direction, between the drain electrode 130 and the gate electrode 140.

In the first direction and second direction, it can also be understood that if the silicon carbide substrate is configured as a reference, the first direction is perpendicular to the main plane of the silicon carbide substrate, and the second direction is parallel to the main plane of the silicon carbide substrate (direction orthogonal to the first direction).

FIG. 4 is a plan view illustrating a configuration of a semiconductor device based on the fundamental ideas, where the sectional view cut by the A-A line in FIG. 4 corresponds to FIG. 3. In FIG. 4, the source electrode 120 and drain electrode 130 respectively extend in the x direction whilst facing each other, and both have a plurality of finger portions protruding in the y direction. Namely, the source electrode 120 and drain electrode 130 of the semiconductor device have a “multi-fingers structure”. Further, the electric field relaxation region 102 includes a region extended from the drain electrode 130 facing towards the gate electrode 140.

A semiconductor device thus configured in which the fundamental ideas are achieved will be explained next. In the fundamental ideas, for a PN junction diode connected in antiparallel to the HEMT, this antiparallel connected PN junction diode is designed so that an avalanche breakdown occurs therein before a drain-source voltage exceeds a withstand voltage of the HEMT. However, what is crucial here is to avoid that the avalanche breakdown occurs in the PN junction diode with a drain-source voltage which is much lower than the withstand voltage of the HEMT. In other words, it is crucial that the avalanche breakdown is made to occur in the PN junction diode with a drain-source voltage which is lower than, but is as close as possible to, the withstand voltage of the HEMT. This is because, if a withstand voltage of the HEMT per se is also 600 V or 1.2 kV, for example, and an avalanche breakdown of about 100 V occurs in the PN junction diode, the 600 V or 1.2 kV cannot be configured as the withstand voltage of the semiconductor device. In other words, for a PN junction diode connected in antiparallel to the HEMT, the fundamental ideas can be to design this antiparallel connected PN junction diode so that the avalanche breakdown occurs therein before the drain-source voltage exceeds the withstand voltage of the HEMT, and to design the PN junction diode so that the avalanche breakdown occurs therein by a drain-source voltage which is as close as possible to the withstand voltage of the HEMT.

In FIG. 3, for example, these fundamental ideas are achieved by designing the electric field relaxation region 102 so that the first virtual line VL1 made to extend (e.g., extending) from an edge of the electric field relaxation region 102 to the z direction intersects with the second virtual line VL2 made to extend (e.g., extending) in the −x direction, between the drain electrode 130 and gate electrode 140. In other words, as illustrated in FIG. 3 and FIG. 4, the fundamental ideas are achieved by configuring the electric field relaxation region 102 so as to include the region extended from the drain electrode 130 facing towards the gate electrode 140.

If, for example, the fundamental ideas are not achieved; namely, if the electric field relaxation region 102 does not extend from the drain electrode 130 facing towards the gate electrode 140, even if a positive electric potential of about 100 V were applied to the drain electrode 130, the depletion layer would not fully spread due to the length of the electric field relaxation region 102 being short, and hence an avalanche breakdown in the PN junction diode would occur. As a result, even in the case that the withstand voltage of the HEMT per se were about 600 V for example, the withstand voltage as a semiconductor device would be about 100 V, as mentioned below.

In contrast, if the electric field relaxation region 102 is configured to include the region extended from the drain electrode 130 facing towards the gate electrode 140, the depletion layer fully spreads due to the long length of the electric field relaxation region 102; as a result, an avalanche breakdown in the PN junction diode would not easily occur with a low drain-source voltage. Thereby, even if the withstand voltage of the HEMT per se were about 600 V, it can be avoided that the withstand voltage as a semiconductor device is about 100 V.

In other words, by designing the impurity concentration of the electric field relaxation region 102 and the length of the electric field relaxation region 102 so as to achieve the fundamental ideas (specifically, design the electric field relaxation region 102 so as to include the region extended from the drain electrode 130 facing towards the gate electrode 140), the depletion layer in the electric field relaxation region 102 can be fully spread out. As a result, the PN junction diode can be designed so that an avalanche breakdown occurs therein with a drain-source voltage which is lower than, but is as close as possible to, the withstand voltage of the HEMT, while this antiparallel connected PN junction diode can also be designed so that the avalanche breakdown occurs therein before the drain-source voltage exceeds the withstand voltage of the HEMT. Furthermore, if the electric field relaxation region 102 is configured so as to include the region extended from the drain electrode 130 facing towards the gate electrode 140, the electric field strength of the surface of the electric field relaxation region 102 becomes small; as a result, the effect of the electric field imparted to the HEMT formed over (e.g., disposed over, formed directly on) top of the electric field relaxation region 102 can be reduced.

### Modified Example

FIG. 5 is a sectional view illustrating a modified example of a semiconductor device based on the fundamental ideas.

FIG. 6 is a plan view illustrating a modified example of a semiconductor device based on the fundamental ideas, where the sectional view cut on the A-A line of FIG. 6 corresponds to FIG. 5.

As illustrated in FIG. 6, the plug PLG1 electrically connecting the source electrode 120 to the silicon carbide epitaxial layer, and the plug PLG2 electrically connecting the drain electrode 130 to the electric field relaxation region 102 can also be disposed on the outer side of the “multi-fingers structure”. In this case, the cell pitch can be miniaturized, and the semiconductor device can thereby become small sized.

### Verification Result

Next, verification results illustrating the usefulness of the fundamental ideas will be explained.

Specifically, simulation results for withstand voltage of the PN junction diode will be explained.

FIG. 7 is a drawing illustrating a device structure in which simulation took place (simulation structure). As illustrated in FIG. 7, the simulation was performed based on a simulation structure where GaN-HEMT was formed over (e.g., disposed over, formed directly on) a PN junction diode having a p⁻SiC region, p⁺SiC region, electric field relaxation region and n⁺SiC region, and where an insulating film (SiO₂ film) was formed over (e.g., disposed over, formed directly on) this GaN-HEMT. For example, an acceptor concentration Nax of the p⁻SiC region was configured as 1×10¹⁶ (cm⁻³), a distance LX between the p⁺SiC region (anode side) and n⁺SiC region (cathode side) was configured as 11 μm, the length of the electric field relaxation region LN and doping concentrations of the donor were changed, and the withstand voltages of the PN junction diode were calculated. This calculation result is illustrated in FIG. 8.

As illustrated in FIG. 8, in order to obtain a high withstand voltage (breakdown voltage) of 600 V or greater for example, it is predicted that 3×10¹² (cm⁻²) or greater is required as the sheet density (DN) of the electric field relaxation region. Moreover, it is expected that by configuring the length of the electric field relaxation region (LN) to be 6 μm or greater, a withstand voltage of 1.2 kV or greater is obtainable. In this FIG. 8, the breakdown voltage increased monotonically until the sheet density (DN) was 1.05×10¹³ (cm⁻²), whereas it decreased at 1.80×10¹³ (cm⁻²).

In FIG. 22, further detailed withstand voltage simulation results are illustrated. In FIG. 22, the acceptor concentration of the p⁻SiC region in FIG. 7 was configured as Nax=7×10¹⁵ (cm⁻³), and the distance between the p⁺SiC region and the n⁺SiC region in FIG. 7 was configured as LX=18 (μm). In FIG. 22, sheet density (DN) increments are provided in detail. Based on FIG. 22, when 600 V was configured as the withstand voltage target, the sheet density (DN) was further narrowed down to 3.42×10¹² (cm⁻²) or greater. It is understood that the sheet density (DN), when 1200 V or greater was configured as the withstand voltage target, should be 8.55×10¹² (cm⁻²) or greater and 1.27×10¹³ (cm⁻²) or less.

In addition, the following became obvious as a result of a variety of simulations. Depending on the targeted withstand voltage, the thickness of the p⁻SiC region, the acceptor concentration Nax of the p⁻SiC region, the distance (LX) between the p⁺SiC region (anode side) and n⁺SiC region (cathode side), and the length of the electric field relaxation region (LN) needed to be adjusted at the appropriate time. Moreover, it was understood that even with the same withstand voltage target, the required acceptor concentration Nax of the p⁻SiC region depends on the thickness of the p⁻Sic region. Meanwhile, it was understood that the optimal sheet density (DN) of the electric field relaxation region does not depend on the targeted withstand voltage. In other words, it was understood that an objective withstand voltage in a shorter distance (LX) between the p⁺SiC region (anode side) and n⁺SiC region (cathode side) is obtainable by configuring the sheet density (DN) to be 8.55×10¹² (cm⁻²) or greater, and 1.27×10¹³ (cm⁻²) or less.

Furthermore, FIG. 9 is a graph illustrating the evaluation result of the withstand voltage test in the OFF state.

FIGS. 9 and 10 are a preview explanation of a portion of the evaluation results of a trial manufactured element mentioned below in FIGS. 12 to 15, which are test results when a transistor to which −3 V was applied between the gate-source is in an OFF state.

As illustrated in FIG. 9, not only in the simulation, but also in the actual withstand voltage test, when a drain current (ID) was gradually increased, destruction did not occur even when increased up to 2 mA/mm. The trial manufactured element used in the measurement had LX=18 (μm), LN=13 (μm), Nax=1×10¹⁶ (cm⁻³), and DN=1.0×10¹³ (cm⁻²). Moreover, an AlN buffer layer with a large bandgap of 6.2 eV was provided between the HEMT and the diode. Thereby, it is understood that a gate current (IG) at the time of breakdown is 1/200 or less of the drain current, the source current (IS) is 1/50 or less of the drain current, and that a breakdown current is flowing in the PN junction diode. Namely, it is understood that an inflow of the breakdown current into the HEMT is suppressed, whilst a non-destructive avalanche breakdown of the PN junction diode occurs to prevent the destruction of the HEMT.

Therefore, as illustrated in FIG. 10, the withstand voltage test could be performed multiple times on the same device. FIG. 10 is a graph which configures FIG. 9 as a linear plot, and which shows the result of multiple sweeps. As illustrated in FIG. 10, it is understood that because the non-destructive avalanche breakdown of the PN junction diode occurs, a stable breakdown also occurs many times.

When a voltage whose the drain current has attained 2 mA/mm was configured as the withstand voltage, the withstand voltage was 1.27 kV. Similar to the simulation result, by forming an electric field relaxation region extended from the drain electrode, a high withstand voltage action of 1.2 kV or greater could be experimentally confirmed.

Based on the above, it is understood that by designing an electric field relaxation region to include a region extended from a drain electrode facing towards a gate electrode, the breakdown voltage of the PN junction diode can be adjusted to a high voltage. This means that, according to the configuration of a semiconductor device based on the fundamental ideas, the PN junction diode can be designed so that an avalanche breakdown occurs therein with a drain-source voltage which is lower than, but is as close as possible to, the withstand voltage of the HEMT, whilst this antiparallel connected PN junction diode can also be designed so that the avalanche breakdown occurs therein before the drain-source voltage exceeds the withstand voltage of the HEMT. Accordingly, the aforementioned verification results support that a semiconductor device, according to the semiconductor device based on the fundamental ideas, can be provided, where this semiconductor device suppresses the inflow of a breakdown current into the HEMT and has a high withstand voltage, whilst preventing the destruction of the HEMT.

### Specific Aspect

A specific aspect of fundamental ideas of the present embodiment which was materialized will be explained next.

FIG. 11 is a sectional view illustrating a configuration of a semiconductor device of the present embodiment.

In FIG. 11, the semiconductor device has a PN junction diode formed over (e.g., disposed over, formed directly on) the silicon carbide substrate 100, and a HEMT formed over (e.g., disposed over, formed directly on) the PN junction diode.

Specifically, the PN junction diode includes the p type silicon carbide epitaxial layer 101 formed over (e.g., disposed over, formed directly on) the silicon carbide substrate 100, and an n type electric field relaxation region (RESURF (REduced SURface Field) region) 102 formed in the silicon carbide epitaxial layer 101. Furthermore, the PN junction diode has a p type semiconductor region 103 with an acceptor concentration higher than the silicon carbide epitaxial layer 101 and formed in the silicon carbide epitaxial layer 101, and a p⁺ type semiconductor region 104 encapsulated in this p type semiconductor region 103. Moreover, the PN junction diode has an n⁺ type semiconductor region 105 encapsulated in the electric field relaxation region 102.

The HEMT is formed over (e.g., disposed over, formed directly on) the PN junction diode. Specifically for example, the buffer layer 110 including aluminum nitride (AlN) is formed over (e.g., disposed over, formed directly on) the PN junction diode of which silicon carbide is configured as the main material, and the channel layer 111 including undoped gallium nitride (GaN) is formed over (e.g., disposed over, formed directly on) this buffer layer 110. At this time, the buffer layer is an undoped layer, or a layer doped with impurities (carbon, iron, magnesium etc.).

Here, the buffer layer 110 is formed with the objective of relaxing the mismatch of the lattice constant of the gallium nitride (GaN) constituting the channel layer 111 and the lattice constant of the silicon carbide constituting the PN junction diode. Namely, if a channel layer 111 including gallium nitride (GaN) is formed directly on silicon carbide, many crystal defects would be formed over (e.g., disposed over, formed directly on) the channel layer 111, which would lead to reduced HEMT performance.

Moreover, because the bandgap energy of AlN is 6.2 eV which is larger than the bandgap energy of silicon carbide which is 3.2 eV, electrons and holes generated by an avalanche breakdown of the PN junction diode utilizing silicon carbide, which flow in towards the GaN side, can be prevented.

Therefore, with the lattice relaxation between the silicon carbide constituting the PN junction diode and the channel layer 111, and the prevention of electrons and holes of the silicon carbide side generated at breakdown from flowing towards the GaN side being configured as the objectives, the buffer layer 110 with a large bandgap is inserted. By forming this buffer layer 110, the quality of the channel layer 111 formed over (e.g., disposed over, formed directly on) the buffer layer 110 can be improved, and the penetration of electrons and holes into the GaN side at the time of breakdown can be suppressed. Thereby, HEMT performance can be improved.

Subsequently, the barrier layer 112 including, for example, undoped aluminum nitride gallium (AlGaN) is formed over (e.g., disposed over, formed directly on) the channel layer 111. Further, the source electrode 120 and the drain electrode 130 are formed to be spaced apart on the barrier layer 112. Namely, the source electrode 120 is formed so as to be in contact with a first region of the barrier layer 112, and the drain electrode 130 is formed so as to be in contact with a second region of the barrier layer 112.

The materials of the source electrode 120 and drain electrode 130 are selected so that this source electrode 120 and the barrier layer 112, or the drain electrode 130 and the barrier layer 112 are in ohmic contact.

Next, a p type cap layer 150 including, e.g., a p type gallium nitride (p-GaN) is formed over (e.g., disposed over, formed directly on) the barrier layer 112 interposed between the spaced apart source electrode 120 and the drain electrode 130, and the gate electrode 140 is formed over (e.g., disposed over, formed directly on) this p type cap layer 150.

Here in the present embodiment, the buffer layer 110, channel layer 111 and barrier layer 112 constituting the HEMT are formed as a mesa structure 115, where on the side surface of both sides of this mesa structure 115, an insulating film 160 including a silicon oxide film is formed, for example.

Further, the source electrode 120 of the HEMT is electrically connected to the p⁺ type semiconductor region 104 of the PN junction diode via the plug PLG1, where the plug PLG1 and the p⁺ type semiconductor region 104 are in ohmic contact. Similarly, the drain electrode 130 of the HEMT is electrically connected to the n⁺ type semiconductor region 105 of the PN junction diode via the plug PLG2, and the plug PLG2 and the n⁺ type semiconductor region 105 are in ohmic contact.

Thereby, with the semiconductor device illustrated in FIG. 11, the PN junction diode becomes connected in antiparallel to the HEMT (refer to FIG. 1).

With a HEMT configured as above, two-dimensional electron gas is generated in the vicinity of the interface of the channel layer 111 and the barrier layer 112. Namely, the electron affinity of the gallium nitride (GaN) constituting the channel layer 111 differs to the electron affinity of the aluminum nitride gallium (AlGaN) constituting the barrier layer 112. Therefore, due to the conducting band offset based on the difference of the electron affinities, as well as the effect of piezoelectric polarization and spontaneous polarization existing in the channel layer 111 and the barrier layer 112, a potential well lower than that of a Fermi level is generated in the vicinity of the interface of the channel layer 111 and the barrier layer 112. As a result, electrons are accumulated in this potential well, and the two-dimensional electron gas is thereby generated in the vicinity of the interface of the channel layer 111 and the barrier layer 112.

Here, with the HEMT illustrated in FIG. 11, because the p type cap layer 150 is formed under the gate electrode 140, a threshold value voltage can be designed to be positive or negative with the structure of the barrier layer 112. For example, the threshold value voltage shifts to the negative direction to the extent that an AlGaN constituting the barrier layer 112 is thick, and the Al composition thereof is large. Specifically, the polarization charge density based on the Al composition can be calculated by the calculating method disclosed in Non patent literature 7, and the threshold value voltage can be designed from the dielectric constant with the thickness of the AlGaN layer. More specifically, when the thickness of the barrier layer 112 is 15 nm, the threshold value voltage becomes positive by configuring the Al composition to be 23% or less, and becomes a normally OFF type. When applying the HEMT to a power convertor, it is often the case that a normally OFF type device is demanded; however, in order to do so it becomes necessary to lower the Al composition, which in conjunction therewith also reduces the two-dimensional electron gas concentration outside the gate electrode just below, and hence the ON resistance tends to increase. Accordingly, it becomes crucial to design the threshold value voltage whilst taking into consideration the trade-off with the ON resistance.

With a semiconductor device thus configured, in FIG. 11, if the stacking direction of the PN junction diode and the HEMT is configured as the first direction (z direction of FIG. 11), and the direction from the drain electrode 130 facing towards the gate electrode 140 is configured as the second direction (−x direction of FIG. 11), in a cross-sectional view, a first virtual line VL1 made to extend (e.g., extending) from an edge of the electric field relaxation region 102 to the z direction intersects with a second virtual line VL2 made to extend (e.g., extending) in the −x direction, between the drain electrode 130 and the gate electrode 140. In other words, the electric field relaxation region 102 includes the region extended from the drain electrode 130 facing towards the gate electrode 140. Moreover, in a cross-sectional view, a third virtual line VL3 made to extend (e.g., extending) from an edge of the p type semiconductor region 103 in the z direction also intersects with a second virtual line VL2 made to extend (e.g., extending) in the −x direction, between the drain electrode 130 and the gate electrode 140. In other words, the p type semiconductor region 103 includes a region extended from the gate electrode 140 facing towards the drain electrode 130.

With the actual device as illustrated in FIG. 11, the electrodes are made to contact with the semiconductor layer via contact holes provided at the insulating film formed over (e.g., disposed over, formed directly on) the semiconductor layer. Thus, in further detail, the source region, gate region and drain region serve as regions where the electrode contacts the semiconductor layer. The extending distance LC of the electric field relaxation region 102 is defined as the extending distance from an edge of the drain region towards a gate electrode direction. The drain region is a region where the drain electrode 130 is in contact with the barrier layer 112, and the edge of the drain region is an edge of this drain region of the near side at the gate electrode 140. The extending distance LA of the p type semiconductor region 103 is defined as the extending distance from the edge of the gate region towards the drain electrode direction. The gate region is the region where the gate electrode 140 is in contact with the p type cap layer 150, and the edge of the gate region is an edge of this gate region of the near side at the drain electrode 130. The distance between the gate-drain serves as the distance between the edge of the gate region and the edge of the drain region.

A semiconductor device of the present embodiment is configured as above.

### Method of Manufacturing a Semiconductor Device

A method of manufacturing a semiconductor device of the present embodiment will be explained next.

FIG. 12 is a flowchart illustrating the flow of the manufacturing steps of the semiconductor device illustrated in FIG. 11, which was actually trial manufactured. As illustrated in FIG. 12, a silicon carbide substrate 100 with an OFF angle greater than 2 degrees and equal to or less than 4 degrees from the (0001) plane is prepared (S101). In the trial manufacture, an n type 4H—SiC substrate (4H-silicon carbide substrate) having an OFF angle of 4 degrees in the <11-20> direction was used. Next, by employing the epitaxial growth by CVD method, a first p type silicon carbide epitaxial layer (thickness 1 μm, acceptor concentration 1×10¹⁸ (cm⁻³)), and a second p type silicon carbide epitaxial layer (thickness 16 μm, acceptor concentration 1×10¹⁶ (cm⁻³)), for example, is formed (S102). Aluminum (Al) was used in the acceptor dopant. Here, the first p type silicon carbide epitaxial layer is not essential, as omitted in the sectional view of FIG. 11. In other words, the silicon carbide epitaxial layer 101 illustrated in FIG. 11 shows the second p type silicon carbide epitaxial layer. Then, by utilizing a photolithography technique and ion implantation technique, the electric field relaxation region 102, the p type semiconductor region 103, the p⁺ type semiconductor region 104 and the n⁺ type semiconductor region 105 were selectively formed in the second p type silicon carbide epitaxial layer, and thereafter impurities were made to be activated by annealing at high temperature (S103).

Here, in the trial manufactured element, the sheet impurity concentration of the electric field relaxation region 102, p type semiconductor region 103, p⁺ type semiconductor region 104 and n⁺ type semiconductor region 105 were respectively configured as 1.0×10¹³ (cm⁻²) (nitrogen (N) implantation), 1.2×10¹⁴ (cm⁻²) (aluminum (Al) implantation), 5×10¹⁵ (cm⁻²) (Al implantation) and 7×10¹⁴ (cm⁻²) (phosphorous (P) implantation).

The dopant concentration of each region can also be modified as follows. For example, the acceptor concentration of the second p type silicon carbide epitaxial layer (the silicon carbide epitaxial layer 101) may be configured as 2×10¹⁵ (cm⁻³) to 1×10¹⁷ (cm⁻³). However, in the case that it is necessary to reduce the thickness of the silicon carbide epitaxial layer 101 and thus configure the acceptor concentration as 1×10¹⁷ (cm⁻³) in accordance with raising the concentration, it is desirable to reduce the thickness of the silicon carbide epitaxial layer 101 to 1 (μm) or less and to configure the silicon carbide substrate 100 to be a high resistance substrate.

The respective ranges of sheet impurity concentrations (cm⁻²) of the electric field relaxation region 102, p type semiconductor region 103, p⁺ type semiconductor region 104 and n⁺ type semiconductor region 105 are as follows. For example, the range of the sheet impurity concentrations of the electric field relaxation region 102 are as mentioned above in FIG. 8 and FIG. 22. The p type semiconductor region 103 is a region having the same conductivity as the silicon carbide epitaxial layer 101, and is not necessarily a region required for device action. However, by forming the p type semiconductor region 103 to be a concentration higher than that of the silicon carbide epitaxial layer 101, penetration of the depletion layer towards the bottom of the gate electrode 140 can be prevented, and by providing the p type semiconductor region 103, the long term reliability for preventing destruction can be improved. Accordingly, the impurity concentration when the p type semiconductor region 103 is provided is desirably higher than the concentration of the two-dimensional electron gas, and specifically a sheet impurity concentration of 1×10¹³ (cm⁻²) or greater is preferable. Since the respective sheet impurity concentrations of the p⁺ type semiconductor region 104 and the n⁺ type semiconductor region 105 may take an ohmic contact, it is preferable to be 5×10¹⁴ (cm⁻²) or greater.

Moreover, a 4H—SiC OFF substrate having a tilt with a predetermined angle from the (0001) plane (Si plane) to the <11-20> direction is typically selected as the silicon carbide substrate 100, as mentioned above. Here, for the main plane of the substrate, there is also an option to utilize a (000-1) plane (C plane) instead of the Si plane. The term {0001} plane is expressed when describing both the (0001) plane and (000-1) plane together. For the tilting crystal direction (OFF direction) of the OFF substrate, there is also an option to utilize <01-10> instead of <11-20>.

Thereafter, the buffer layer 110 including AlN, the channel layer 111 (thickness 800 nm) including GaN, the barrier layer 112 (Al composition 23%, thickness 20 nm) including AlGaN, and the p type cap layer 150 (thickness 60 nm) including p type GaN are formed by means of the MOCVD method, and activation treatment of impurities including magnesium (Mg) takes place (S104).

Next, photolithography techniques and dry etching techniques are utilized to form a mesa structure (S105). Subsequently, a nickel film (Ni film) is deposited on a silicon carbide surface; thereafter, the plug PLG1 and the plug PLG2 serving as ohmic electrodes are formed by the sintering process. Furthermore, Al/Ti-based electrodes are formed over (e.g., disposed over, formed directly on) the barrier layer 112 as the source electrode 120 and drain electrode 130, and a nickel film (Ni) was deposited the gate electrode 140; thereafter ohmic electrodes are formed subjecting this to thermal treatment (S106). Thereafter, after protecting the surfaces with insulating film, for example, a pad electrode is formed. A semiconductor device of the present embodiment can thereby be manufactured. In this trial manufacture, the gate electrode 140 was configured as an ohmic electrode utilizing Ni; however, a Schottky electrode made of a TiN-based alloy or Al/Ti-based alloy etc., for example, may also be used.

### Element Characteristics of the Trial Manufactured Device

Next, the evaluation result of the element characteristics of the device trial manufactured by the aforementioned method of manufacturing is mentioned.

In the below evaluation results, the conditions of the trial manufactured device were that the distance between the gate-drain was 26 (μm), the extending distance of the electric field relaxation region 102 (LC of FIG. 11) was 15 (μm), and the sheet impurity concentration of the donor of the electric field relaxation region 102 was 1.0×10¹³ (cm⁻²). Moreover, the extending distance of the p type semiconductor region 103 (LA of FIG. 11) was 6 (μm), and the sheet impurity concentration of the acceptor was 1.2×10¹⁴ (cm⁻²). The sheet impurity concentration of the p⁺ type semiconductor region 104 and the n⁺ type semiconductor region 105 for forming a good ohmic contact with SiC was 5×10¹⁴ (cm⁻²) or greater.

FIG. 13 illustrates the experimentation result of I_{D}-V_{Ds} characteristics in the ON state. As illustrated in FIG. 13, this device shows a high current carrying capability of 300 mA/mm, where a low value of 47 Ωmm was obtained in the ON resistance per gate width. In this trial manufacture, a silicon carbide substrate with an OFF of 4 degrees is used, unlike the “on-axis substrate” normally used in a HEMT, and thus a surface roughness of the HEMT structure of about 30 nm was observed. However, as a characteristic of the ON state, it was understood that values similar to that of a normal HEMT were obtainable, and that a high mobility of the two-dimensional electron gas was obtainable.

The Hall measurement for the mobility of the two-dimensional electron gas took place separately. Namely, a sample for the measurement of the Hall effect was created by having formed a HEMT structure on a silicon carbide substrate with an OFF of 4 degrees towards the <11-20> direction. As a result, the mobility at room temperature (300K) was 1550 (cm²/Vs) and the mobility at low temperature (80K), where a tendency of monotonic increase together with the temperature reduction was obtainable, was 8720 (cm²/Vs). This result indicates that the two-dimensional electron gas has a mobility limited to phonon scattering having physical properties. In other words, it was confirmed that even for silicon carbide substrate with an OFF of 4 degrees, which has until now been avoided with GaN-based crystal growth, electrical characteristics equivalent to those of the “on-axis substrate” commonly used in HEMT are obtainable.

The top data reported until now of the HEMT with a 1.2 kV withstand voltage using the “on-axis substrate” is about 20 Ωmm. For this trial manufacture device, good characteristics of the same order as that of the top data were obtainable for the ON resistance in the initial trial manufacture, and compared with the material limit of the Si lateral transistor, a low ON resistance of about 1/100 was obtained.

FIG. 14 illustrates the experimentation result of transmission characteristics for Vds=5V. The gate threshold value voltage was −0.25V when determined at Id=1 μA/mm, which is a common definition in HEMT. Since the threshold value voltage is negative, this trial manufactured device was a normally ON type.

As illustrated in the aforementioned FIGS. 9 and 10, the withstand voltage of this device was 1.2 kV or greater and non-destructive. Moreover, the gate current at the time of breakdown was suppressed to 1/200 or less relative to the drain current.

FIG. 15 illustrates the experimentation results of Id-Vds characteristics for a negative Vds, at Vgs=−4V. Here, a negative Vds corresponds to a forward bias relative to a silicon carbide PN junction diode. Therefore, if the drain-source voltage attains about −3V which is a build-in voltage in the PN junction of silicon carbide, a current begins to flow via the integrated silicon carbide PN junction diode (IB in FIG. 15). If the voltage falls further, similarly to a conventional HEMT, a gate channel of the HEMT opens and a current also flows from the channel of the HEMT, and thus it was observed that a current flowing via a silicon carbide PN junction diode was added (ID in FIG. 15).

Moreover, also in FIG. 11, a comparative device with no doping of the electric field relaxation region 102; in other words, a comparative device in which the electric field relaxation region does not extend from the drain electrode was created. The evaluation result of the breakdown voltage of the diode in the comparative device was low at about 100V. It was understood that the electric field relaxation region 102 extending from the drain electrode is essential in order to obtain a high breakdown voltage.

### Features of the Embodiments

The features of the present embodiment will be explained next.

The first feature of the present embodiment is that the electric field relaxation region 102 includes the region extended from the drain electrode 130 facing towards the gate electrode 140 as illustrated in FIG. 11, for example. In other words, in FIG. 11, if the stacking direction of the PN junction diode and the HEMT is configured as the first direction (z direction of FIG. 11), and the direction from the drain electrode 130 facing towards the gate electrode 140 is configured as the second direction (−x direction of FIG. 11), the first feature of the present embodiment, in a cross-sectional view, is that a first virtual line VL1 made to extend (e.g., extending) from an edge of the electric field relaxation region 102 to the z direction intersects with a second virtual line VL2 made to extend (e.g., extending) in the −x direction, between the drain electrode 130 and the gate electrode 140. Thereby, according to the present embodiment, since the length of the electric field relaxation region 102 is long, in the case that a reverse bias is applied to the PN junction diode, the depletion layer in the electric field relaxation region 102 can be fully spread out. As a result, the PN junction diode can also be designed so that an avalanche breakdown occurs therein with a drain-source voltage which is lower than, but is as close as possible to, the withstand voltage of the HEMT, whilst this antiparallel connected PN junction diode can also be designed so that the avalanche breakdown occurs therein before the drain-source voltage exceeds the withstand voltage of the HEMT. In other words, the breakdown voltage of the PN junction diode is lower than the withstand voltage between the drain-source of the HEMT. Therefore, according to the first feature of the present embodiment, the withstand voltage of the semiconductor device can be ensured whilst preventing the destruction of the HEMT.

Next, the second feature of the present embodiment is that a buffer layer with a bandgap larger than that of the silicon carbide is provided between the HEMT and PN junction diode. Thereby, the flowing of electrons and holes of the PN junction diode generated during an avalanche breakdown into the gate electrode of the HEMT can be suppressed. This is because, the band offset of the buffer layer against the silicon carbide functions as a wall against the electrons and holes.

Next, the third feature of the present embodiment is that the HEMT is utilized as a power transistor. Thereby, a high conduction capability in the forward direction can be ensured in a semiconductor device including the HEMT and PN junction diode. In other words, according to the present embodiment, conduction loss in the forward direction can be reduced. This is because HEMT has a high conduction capability.

Here, the reason that a high HEMT conduction capability was obtained is because it was integrated with the silicon carbide PN junction diode, which has a critical electric field strength equal to that of GaN. Therefore, about 1.2 kV was obtainable as a non-destructive breakdown voltage of the silicon carbide PN junction diode, with the distance between the gate-drain being a small dimension of 26 μm. Even if combined with a silicon PN junction diode, 120 μm or greater in the horizontal direction is required between the cathode-anode in order to obtain a withstand voltage of 1.2 kV, and the distance between the gate-drain of the HEMT is longer than this. Naturally, this leads to a huge increase of the ON resistance and chip area. Therefore, it is not practical to use a silicon PN junction diode. Namely, indeed because the HEMT was integrated with a silicon carbide PN junction diode, the distance between the gate-drain of the HEMT can be made shorter whilst about 1.2 kV can be ensured as the non-destructive breakdown voltage of the silicon carbide PN junction diode. Thereby, a high conduction capability in the HEMT can be obtained.

Meanwhile, the idea of forming a GaN-based PN junction diode between the channel layer and buffer layer can also be considered. However, with a GaN-based diode, it is very difficult to form a p type region by means of ion implantation. Specifically, in order to activate Mg which is an acceptor impurity after the ion implantation, a high temperature annealing of 1300° C. or higher is necessary. Meanwhile, thermal decomposition occurs with a GaN-based diode at a temperature of 1000° C. or higher under atmospheric pressure. In order to suppress thermal decomposition, annealing must take place under a high pressure nitrogen atmosphere of 10,000 atm or higher. Accordingly, the production of a GaN-based lateral PN junction diode is industrially very difficult. As methods of selectively forming a p type region of a GaN-based PN junction diode on a planar surface, there are also technological ideas of combining etching, selected region crystal growth, the planarization of a crystal plane by means of CMP etc. However, for these techniques there are high industrial hurdles such as in mass production and yield, and hence there are concerns that these would raise costs.

The fourth feature of the present embodiment is that the PN junction diode is connected in antiparallel to the HEMT. Thereby, a high conduction capability in the reverse direction can be ensured. Namely, according to the present embodiment, conduction loss in the reverse direction can be reduced.

For example, when a circuit containing an inductance such as a motor is connected to a load, there is a mode in which a load current flows in the direction reverse to that of a switch which is ON (freewheeling mode). In this freewheeling mode, the source potential is higher than the drain potential, and the current flows in the reverse direction which differs to the normally forward direction (direction from the source electrode 120 towards the drain electrode 130).

In the present embodiment, the PN junction diode is connected in antiparallel to the HEMT at this time. As a result, in the freewheeling mode, in addition to the reverse direction current by the HEMT, a forward direction current also flows by the PN junction diode connected in antiparallel to the HEMT. Therefore, according to the fourth feature of the present embodiment, more reverse direction current can flow by the forward direction current flowing in the PN junction diode connected in antiparallel to the HEMT, than by a normal semiconductor device configured from a HEMT alone. Thereby, according to semiconductor device of the present embodiment, a remarkable effect of being able to reduce conduction loss in the reverse direction is obtainable.

The fifth feature of the present embodiment will be explained next.

For example, in the present embodiment, a silicon carbide-based PN junction diode is formed over (e.g., disposed over, formed directly on) a high resistance silicon carbide substrate, and a GaN-based HEMT is formed over (e.g., disposed over, formed directly on) this PN junction diode. Here, the reason that a high resistance silicon carbide substrate is utilized is because of the obtainability of advantages such as being able to reduce power loss at high frequency, and having excellent heat dissipation characteristics due to having a high heat conductivity. Accordingly, in the present embodiment, a silicon carbide-based PN junction diode is formed over (e.g., disposed over, formed directly on) a high resistance silicon carbide substrate, and a GaN-based HEMT is formed over (e.g., disposed over, formed directly on) this PN junction diode.

In relation to this point, when forming a silicon carbide-based PN junction diode on a silicon carbide substrate, it can be considered to adopt a vertical PN junction diode allowing the current to flow in the thickness direction of the substrate, for example. However, it is known that when forming a vertical PN junction diode on a silicon carbide substrate, by allowing the current to flow for a long time in the vertical direction (thickness direction of substrate), a “forward current degradation phenomenon” in which a forward direction current is reduced. This is considered to be due to a basal plane dislocation formed over (e.g., disposed over, formed directly on) the interface of the silicon carbide substrate and silicon carbide epitaxial layer.

Thus, in the present embodiment, a vertical PN junction diode is not formed over (e.g., disposed over, formed directly on) a silicon carbide substrate, but a lateral PN junction diode allowing the current to flow in the horizontal direction of the substrate, is formed. This is the fifth feature of the present embodiment. Namely, the fifth feature of the present embodiment is that a lateral PN junction diode is formed over (e.g., disposed over, formed directly on) a high resistance silicon carbide substrate.

In this case, with a lateral PN junction diode, because current flows in the surface of the silicon carbide epitaxial layer, no current flows at the basal plane dislocation formed at the interface of the silicon carbide substrate and silicon carbide epitaxial layer. As a result, according to the fifth feature of the present embodiment, a “forward current degradation phenomenon”; that is, a decrease in the forward direction current, can be suppressed.

Next, as illustrated in FIG. 11 for example, the sixth feature of the present embodiment is that the p type semiconductor region 103 is provided, and in a cross-sectional view, a third virtual line VL3 made to extend (e.g., extending) from an edge of the p type semiconductor region 103 in the z direction intersects with the second virtual line VL2 made to extend (e.g., extending) in the −x direction, between the drain electrode 130 and the gate electrode 140. In other words, the sixth feature of the present embodiment is that the p type semiconductor region 103 includes the region extending from the gate electrode 140 facing towards the drain electrode 130.

Thereby, according to the present embodiment, the ON resistance of the PN junction diode can be reduced. Furthermore, the p type semiconductor region 103 is electrically connected to the source electrode 120, and “0V” is applied to the source electrode 120. Therefore, the “0V” is also applied to the p type semiconductor region 103. Further, according to the sixth feature of the present embodiment, since the p type semiconductor region 103 includes the region extended from the gate electrode 140 facing towards the drain electrode 130, this p type semiconductor region 103 has a function relaxing the effect of the electric field applied to the HEMT, similar to a “field plate” for a HEMT formed over (e.g., disposed over, formed directly on) top of the PN junction diode. As a result, according to the sixth feature of the present embodiment, the withstand voltage of the HEMT can be improved.

Here, an example of providing the p type semiconductor region 103 was explained; however, the p type semiconductor region 103 is not a required constituent element, and the p type semiconductor region 103 also need not be provided.

The seventh feature of the present embodiment is that, as illustrated in FIG. 11 for example, a side surface of the mesa structure 115 is covered by the insulating film 160. Thereby, according to the present embodiment, a leakage current from the side surface of the mesa structure 115 can be reduced in the HEMT.

Here, an example of forming the insulating film 160 so as to cover the side surface of the mesa structure 115 was explained; however, the insulating film 160 covering the side surface of the mesa structure 115 is not a required constituent element, and the insulating film 160 also need not be provided.

Next, the eighth feature of the present embodiment will be explained.

In the present embodiment, the crystal growth of the silicon carbide epitaxial layer and nitride semiconductor layer (AlN layer, GaN layer, AlGaN layer) on the 4H—SiC substrate (silicon carbide substrate) is obtainable.

Here, the mixing of polytypes other than 4H such as 6H, for example, is prevented by performing an epitaxial growth of a 4H—SiC layer on a 4H—SiC substrate; the so-called homo-epitaxial crystal growth. Hence, a 4H—SiC substrate, in which a slight tilt (OFF angle) of 4 degrees or more is provided to a crystal orientation <11-20> direction relative to a (0001) plane which is a growth plane, is generally used.

Meanwhile, since a GaN single crystal substrate is in development and hence very expensive, there is a practical application for a hetero epitaxial crystal growth method using an alternative single crystal substrate on the assumption of a lattice mismatch. The difference of the lattice constant of the 4H—SiC substrate is about 3.3% relative to a GaN single crystal, and a technique of growing a nitride semiconductor layer with a comparatively good crystallinity on top of the substrate is known. This technique has a practical application with the organometallic vapor phase growth method (MOCVD method) which has excellent mass productivity. This objective silicon carbide substrate is a template for directly forming a nitride semiconductor layer without growing a SiC layer, and an “on-axis substrate” is said to be good. The “on-axis substrate” is a substrate which does not tilt from a growth plane (0001) plane (has no OFF angle), and errors in the OFF angle of the “on-axis substrate” is within 0.25 degrees by standard specification. Such an “on-axis substrate” is said to be unsuitable for normal SiC layer homo-epitaxial growth because of the difficulty to suppress polytypes.

Based on the above, in the present embodiment, the crystal growth of a silicon carbide epitaxial layer and nitride semiconductor layer on a silicon carbide substrate is necessary; however, it is common to utilize a silicon carbide substrate having an OFF angle in the crystal growth of the silicon carbide epitaxial layer (Knowledge 1). In contrast, it is common to use an “on-axis substrate” in the crystal growth of a nitride semiconductor layer by means of the MOCVD method (Knowledge 2). Accordingly, when manufacturing a semiconductor device of the present embodiment, it is difficult to balance the mutually contradicting Knowledge 1 and Knowledge 2, and hence the crystal growth of a silicon carbide epitaxial layer and nitride semiconductor layer on a silicon carbide substrate is technologically difficult to perform well.

In relation to this point, as a result of having keenly investigated this technological difficulty, the present inventors newly discovered that by utilizing, e.g., a silicon carbide substrate having an OFF angle greater than 2 degrees and equal to or less than 4 degrees, the mobility of a HEMT utilizing a nitride semiconductor layer having had crystal growth by the MOCVD method can be ensured, whilst performing crystal growth of a good silicon carbide epitaxial layer. Namely, the eighth feature of the present embodiment is that a silicon carbide substrate having an OFF angle greater than 2 degrees and equal to or less than 4 degrees is utilized. Further, according to this eighth feature of the present embodiment, the performance of a semiconductor device including the HEMT and PN junction diode can be ensured.

### Modified Example

### «Variation of the Electric Field Relaxation Region»

A modified example of the electric field relaxation region 102, which is a main constituent element of the embodiment is explained as follows. The reason why a modified example would be necessary is as follows. Generally, in order to improve the performance and reduce the cost of a transistor, it is demanded to shorten the distance between the gate electrode 140 and drain electrode 130 whilst maintaining a desired withstand voltage. Namely, it is demanded to further shorten a distance (LX) between a p⁺SiC region (anode side) and n⁺SiC region (cathode side) whilst maintaining a desired withstand voltage. Furthermore, in order to reduce costs, it is desirable to obtain a targeted withstand voltage in a thinner p⁻SiC region (the silicon carbide epitaxial layer 101). In order to do so, the method of spatially modulating the sheet density (DN) of the electric field relaxation region 102 is effective. However, even in the case that the sheet density (DN) is spatially modulated, at least one area of the electric field relaxation region 102 is required to have a sheet density (DN) of 8.55×10¹² (cm⁻²) or greater, and 1.27×10¹³ (cm⁻²) or less. From the aforementioned viewpoint, variations of the electric field relaxation region are illustrated as follows.

As illustrated in FIG. 16, by thinning a portion of the electric field relaxation region 102 just below the plug PLG2, the withstand voltage of the vertical direction can be ensured, whilst also reducing the thickness of the silicon carbide epitaxial layer 101. In this case, since the thickness of the silicon carbide epitaxial layer 101 can be reduced, the manufacturing cost of the semiconductor device can be reduced.

As illustrated in FIG. 17, by providing a tilt in the electric field relaxation region 102, the withstand voltage can be made to be improved in the distance between the same gate electrode-drain electrode. As a result, this can promote the semiconductor device to become small sized. Although not illustrated in the sectional view of FIG. 17, the electric field relaxation region 102 which is provided in an island shape is made to be in contact with all drain electrodes in the depth direction etc. Thereby, electrons in the electric field relaxation region 102 are quickly re-implanted at the turn ON.

However, the tilted electric field relaxation region 102 illustrated in FIG. 17 is difficult to manufacture, in terms of the manufacturing process. Accordingly, taking the manufacturability into consideration, as illustrated in FIG. 18 for example, in order to form the electric field relaxation region 102, by performing ion implantation multiple times in which the implantation energy was changed, a structure corresponding to the tilted electric field relax region 102 illustrated in FIG. 17 can be easily manufactured. Moreover, by forming an electric field relaxation region 102 as illustrated in FIG. 19, the number of times that the ion implantation is performed can be reduced, which can thereby reduce the manufacturing cost of the semiconductor device.

As illustrated in FIG. 20, by embedding a portion of the electric field relaxation region 102 in the silicon carbide epitaxial layer 101, the impurity concentration of the electric field relaxation region 102 can be improved, whilst also ensuring the withstand voltage of the PN junction diode. As a result, the conduction loss in the semiconductor device can be reduced. Furthermore, as illustrated in FIG. 21, by overlapping the p type semiconductor region 103 and the electric field relaxation region 102 to form the so-called “super junction structure”, the impurity concentration of the electric field relaxation region 102 can become highly concentrated, the length of the electric field relaxation region 102 can be made longer, and the conduction loss can thus be reduced whilst ensuring the withstand voltage.

### «HEMT Structure Variations»

In the embodiments, AlN layer was used for the buffer layer of the HEMT; however, this can also be changed to AlGaN, which has a bandgap energy sufficiently larger than silicon carbide. Specifically, an AlGaN with a bandgap energy of 4 eV or greater and an Al composition of 30% or greater can be used. Namely, a buffer layer can also be configured from AlₓGa₁₋ₓN having an aluminum (Al) composition X greater than 30%.

Moreover, although AlGaN is utilized in the barrier layer of the HEMT, this can be changed to a Group III to V nitride semiconductor mixed crystal such as InAlN, InGaAlN etc., which has a bandgap energy larger than that of the GaN which serves as a channel layer. Moreover, by configuring the barrier layer not as a single layer, but as a plurality of Group III to V nitride semiconductor mixed crystals, the HEMT performance can be improved. For example, the barrier layer can be configured to be AlGaN/AlN (with AlN at the lower side). Thereby, the mobility of the two-dimensional electron gas can be improved. Moreover, the barrier layer can be configured to be GaN/AlGaN (with AlGaN at the lower side). Current collapse can thereby be reduced.

Furthermore, a Group III to V nitride semiconductor with a bandgap energy larger than that of the GaN, which serves as a channel, can be additionally inserted between the buffer layer and channel layer. Thereby, confinement of the two-dimensional electron gas can be enhanced, and drain leakage current in the OFF state can be reduced.

In the embodiments, a structure forming an ohmic electrode using a Ni-based alloy with respect to the p type GaN (the p type cap layer 150) is adopted as the gate structure of the HEMT. In relation to this point, a similar ohmic electrode using a Pt-based alloy can also be formed.

Moreover, instead of the p type GaN under the gate electrode, another p type Group III to V nitride semiconductor mixed crystal can also be adopted. For example, a p type InGaN, AlInN or AlGaN (Non patent literature 2, FIG. 8 (b)) etc. may also be adopted.

Furthermore, the gate electrode can also be changed to a Schottky electrode with respect to the p type GaN. Examples of representative Schottky electrodes include Al/Ti or Ti-based alloys such as TiN. Thereby, gate leakage current when a positive voltage was applied to a gate electrode can be reduced and a higher voltage (about 5V to 8V) can be applied to the gate electrode.

Moreover, the p type GaN under the gate electrode can be eliminated and an insulating layer can be provided (Non patent literature 2, FIG. 8 (c), (e), (f)). At this time, by performing: a fluorine plasma treatment at the AlGaN barrier layer under the gate electrode (Non patent literature 2, FIG. 8 (c)); or etching the barrier layer until mid-way by dry etching (Non patent literature 2, FIG. 8 (e)); or etching by penetrating the barrier layer (Non patent literature 2, FIG. 8 (f)), a gate leakage current is reduced by means of an insulating gate structure whilst the threshold value voltage is controlled. Thereby, a higher gate voltage (about 15V to 30V) can be utilized.

«Variations of the field plate structure of the HEMT»

Although not illustrated in the drawings, various kinds of field plate structures reported until now may also be adopted in the semiconductor device of the embodiments. For example, it is envisaged in the embodiments to comprise three types field plate structures connected to the gate electrode 140, the source electrode 120 and the drain electrode 130. Thereby, destruction in the GaN structure, HEMT can be prevented, and high withstand voltage action of 1.2 kV or greater can be achieved.

A field plate structure connected to the source electrode 120 may also be adopted as a variation of a field plate structure (Non patent literature 3, FIG. 1 (a)). Moreover, a field plate structure connected to the drain electrode 130 can also be adopted (Non patent literature 3, FIG. 1 (b)). Furthermore, in addition to a field plate structure being connected to the source electrode 120, a field plate structure connected the gate electrode 140 can also be adopted (Non patent literature 4, FIG. 1 (a)).

The number of steps can also be increased in a field plate connected to the gate electrode 140, the source electrode 120 and the drain electrode 130. For example, an improved high withstand voltage by means of configuring a field plate connected to the gate electrode 140 to be two-steps has been reported (Non patent literature 5, FIG. 1 (a)). A structure in which the number of steps of the field plate was thus increased can be adopted. However, in order to increase the number of steps, the photo-lithography process increases, hence increasing manufacturing cost. Taking this into consideration, a structure whose field plate was tilted may also be adopted (Non patent literature 6, FIG. 1).

The invention conceived by the present inventors was specifically explained as above based on the embodiments thereof; however, of course the present invention is not limited to the embodiments and can be variously changed in a scope that does not deviate from the gist thereof.

### REFERENCE SIGNS LIST

10 Switching circuit
100 Silicon carbide substrate
101 Silicon carbide epitaxial layer
102 Electric field relaxation region
103 p type semiconductor region
104 p⁺ type semiconductor region
105 n⁺ type semiconductor region
110 Buffer layer
111 Channel layer
112 Barrier layer
115 Mesa structure
120 Source electrode
130 Drain electrode
140 Gate electrode
150 p type cap layer
160 Insulating film
A Anode
C Cathode
D Drain
FRD Diode
G Gate electrode
PLG1 Plug
PLG2 Plug
Q1 Power transistor
S Source
VL1 First virtual line
VL2 Second virtual line
VL3 Third virtual line

1. A semiconductor device comprising:
a PN junction diode disposed over a silicon carbide substrate; and
a high electron mobility transistor disposed over the PN junction diode, wherein:
the PN junction diode includes:
a silicon carbide epitaxial layer of a first conduction type disposed over the silicon carbide substrate; and
an electric field relaxation region of a second conduction type formed in the silicon carbide epitaxial layer, the second conduction type being configured to flow current in a direction opposite being to that of the first conduction type;
the high electron mobility transistor includes
a channel layer including a first nitride semiconductor layer,
a barrier layer including a second nitride semiconductor layer in contact with the channel layer,
a buffer layer including a third nitride semiconductor layer provided between the channel layer and the silicon carbide epitaxial layer, the buffer layer having a bandgap larger than that of the silicon carbide epitaxial layer,
a source electrode in contact with a first region of the barrier layer,
a drain electrode in contact with a second region of the barrier layer, and
a gate electrode provided between the source electrode and the drain electrode;
the silicon carbide epitaxial layer is electrically connected to the source electrode;
the electric field relaxation region is electrically connected to the drain electrode; and
in a plan view, the electric field relaxation region includes a region extended from the drain electrode.

2. The semiconductor device according to claim 1, wherein
in response to a stacking direction of the PN junction diode and the high electron mobility transistor being configured as a first direction, and a direction orthogonal to the first direction is configured as a second direction, in a cross-sectional view, a first virtual line extending from an edge of the electric field relaxation region towards the first direction intersects with a second virtual line extending in the second direction, between the drain electrode and the gate electrode.

3. The semiconductor device according to claim 2, wherein
a breakdown voltage of the PN junction diode is lower than a withstand voltage of the high electron mobility transistor in a drain-source voltage, the drain-source voltage being a difference between a drain potential applied to the drain electrode and a source potential applied to the source electrode.

4. The semiconductor device according to claim 3, wherein
the PN junction diode comprises a function, by means of an occurrence of an avalanche breakdown, preventing the destructive breakdown mode of the high electron mobility transistor which occurs when the drain-source voltage exceeds a withstand voltage of the high electron mobility transistor.

5. The semiconductor device according to claim 2, wherein
the PN junction diode comprises a semiconductor region of the first conduction type formed in the silicon carbide epitaxial layer, the semiconductor region having an impurity concentration higher than that of the silicon carbide epitaxial layer, and the semiconductor region being electrically connected to the source electrode.

6. The semiconductor device according to claim 5, wherein
in a cross-sectional view, a third virtual line extending from an edge of the semiconductor region towards the first direction intersects with a second virtual line extending in the second direction, between the drain electrode and the gate electrode.

7. The semiconductor device according to claim 6, wherein
the semiconductor region comprises a function relaxing the effect of the electric field applied to the high electron mobility transistor.

8. The semiconductor device according to claim 1, wherein
the buffer layer is AlₓGa₁₋ₓN having an aluminum (Al) composition X greater than 30%.

9. The semiconductor device according to claim 1, wherein
the buffer layer is AlN.

10. The semiconductor device according to claim 1, wherein
the first conduction type is a p type,
the second conduction type is an n type, and
the PN junction diode is a lateral diode having a dominant current path in a direction parallel to a main plane of the silicon carbide epitaxial layer.

11. The semiconductor device according to claim 1, wherein
the silicon carbide substrate is a 4H-silicon carbide substrate comprising a main plane on which the silicon carbide epitaxial layer is formed, wherein the main plane comprises an OFF angle greater than 2 degrees and equal to or less than 4 degrees in a predetermined crystal direction from a {0001} plane.

12. The semiconductor device according to claim 1, wherein
the channel layer and the barrier layer are formed as a mesa structure, and
a side surface of the mesa structure is covered with an insulating film.

13. The semiconductor device according to claim 1, comprising a breakdown voltage of 600V or greater between the source electrode and the drain electrode, wherein
a sheet impurity concentration of a donor added to the electric field relaxation region is 3.42×10¹² (cm⁻²) or greater.

14. The semiconductor device according to claim 1, comprising a breakdown voltage of 1200V or greater between the source electrode and the drain electrode, wherein
a sheet impurity concentration of a donor added to the electric field relaxation region is 8.55×10¹² (cm⁻²) or greater, and 1.27×10¹³ (cm⁻²) or less.

15. The semiconductor device according to claim 1, wherein
the PN junction diode is a lateral diode having a dominant current path in a direction parallel to a main plane of the silicon carbide epitaxial layer.

16.-20. (canceled)

21. A semiconductor device comprising:
a PN junction diode disposed over a silicon carbide substrate; and
a high electron mobility transistor disposed over the PN junction diode, wherein:
the PN junction diode includes:
a silicon carbide epitaxial layer of a first conduction type disposed over the silicon carbide substrate; and
an electric field relaxation region of a second conduction type formed in the silicon carbide epitaxial layer, the second conduction type being configured to flow current in a direction opposite being to that of the first conduction type;
the high electron mobility transistor includes:
a channel layer including a first nitride semiconductor layer,
a barrier layer including a second nitride semiconductor layer in contact with the channel layer,
a buffer layer including a third nitride semiconductor layer provided between the channel layer and the silicon carbide epitaxial layer,
a source electrode in contact with a first region of the barrier layer,
a drain electrode in contact with a second region of the barrier layer, and
a gate electrode provided between the source electrode and the drain electrode;
the silicon carbide epitaxial layer is electrically connected to the source electrode;
the electric field relaxation region is electrically connected to the drain electrode; and
the PN junction diode is a lateral diode having a dominant current path in a direction parallel to a main plane of the silicon carbide epitaxial layer.

22. The semiconductor device according to claim 21, wherein in a plan view, the electric field relaxation region includes a region extended from the drain electrode.
